(19) United States
(12) Patent Application Publication
(10) Pub. No.: US 2024/0347521 A1
(43) Pub. Date: Oct. 17, 2024

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Yoshitaka KATO, Nisshin-shi (JP); Takeshi ENDO, Nisshin-shi (JP); Hiroshi ISHINO, Nisshin-shi (JP)

(21) Appl. No.: 18/594,334

(22) Filed: Mar. 4, 2024

(30) Foreign Application Priority Data
Apr. 17, 2023 (JP) 2023-067362

(51) Int. Cl. H01L 25/16; H01L 23/00; H01L 23/31; H01L 23/42

(52) U.S. Cl. CPC H01L 25/162; H01L 23/42; H01L 23/3121; H01L 24/29; H01L 24/32; H01L 24/33; H01L 2224/29139; H01L 2224/32225; H01L 2224/33181

(57) ABSTRACT

A semiconductor device includes a semiconductor module, a wiring substrate, a sealing member, and a thermal diffusion plate. The semiconductor module includes a semiconductor chip in which a semiconductor element is disposed. The wiring substrate is electrically connected to the semiconductor module. The sealing member seals the semiconductor module and the wiring substrate. The thermal diffusion plate is disposed between the semiconductor module and the wiring substrate, and has a thermal conductivity higher than a thermal conductivity of the sealing member. The thermal diffusion plate has a plate shape and is disposed in the sealing member in a state where a plane direction of the thermal diffusion plate is along a direction intersecting an arrangement direction of the semiconductor module and the wiring substrate.

### CROSS REFERENCE TO RELATED APPLICATION

The present application claims the benefit of priority from Japanese Patent Application No. 2023-067362 filed on Apr. 17, 2023. The entire disclosure of the above application is incorporated herein by reference.

### TECHNICAL FIELD

The present disclosure relates to a semiconductor device.

### BACKGROUND

Conventionally, there has been known a semiconductor device in which a semiconductor chip and a wiring substrate are sealed with a sealing member.

### SUMMARY

The present disclosure provides a semiconductor device including a semiconductor module, a wiring substrate, a sealing member, and a thermal diffusion plate. The semiconductor module includes a semiconductor chip in which a semiconductor element is disposed. The wiring substrate is electrically connected to the semiconductor module. The sealing member seals the semiconductor module and the wiring substrate. The thermal diffusion plate is disposed between the semiconductor module and the wiring substrate, and has a thermal conductivity that is higher than a thermal conductivity of the sealing member. The thermal diffusion plate has a plate shape and is disposed in the sealing member in a state where a plane direction of the thermal diffusion plate is along a direction intersecting an arrangement direction of the semiconductor module and the wiring substrate.

### BRIEF DESCRIPTION OF DRAWINGS

Objects, features and advantages of the present disclosure will become apparent from the following detailed description made with reference to the accompanying drawings. In the drawings:

FIG. 1 is a perspective view of a semiconductor device according to a first embodiment;

FIG. 2 is a cross-sectional view of the semiconductor device taken along line II-II in FIG. 1;

FIG. 3 is a cross-sectional view of the semiconductor device taken along line III-III in FIG. 1;

FIG. 4 is a cross-sectional view of the semiconductor device taken along line IV-IV in FIG. 1;

FIG. 5 is a plan view of a support substrate shown in FIG. 1;

FIG. 6 is a plan view of a first sealing member shown in FIG. 1;

FIG. 7 is a diagram showing a simplified model used for simulations;

FIG. 8A is a diagram showing a simulation result regarding a temperature in a case where an area of a thermal diffusion plate is set to be equal to an area of a semiconductor chip;

FIG. 8B is a diagram showing a simulation result regarding the temperature in a case where the area of the thermal diffusion plate is set to be twice the area of the semiconductor chip;

FIG. 8C is a diagram showing a simulation result regarding the temperature in a case where the area of the thermal diffusion plate is set to be four times the area of the semiconductor chip;

FIG. 9 is a graph showing a relationship between a ratio of the area of the thermal diffusion plate to the area of the semiconductor chip and the maximum temperature of a driving IC chip;

FIG. 10A is a diagram showing a simulation result regarding the temperature in a case where a thermal conductivity of the thermal diffusion plate is set to be equal to a thermal conductivity of a sealing member;

FIG. 10B is a diagram showing a simulation result regarding the temperature in a case where the thermal conductivity of the thermal diffusion plate is set to be about 442 times the thermal conductivity of the sealing member;

FIG. 11 is a graph showing a relationship between a ratio of the thermal conductivity of the thermal diffusion plate to the thermal conductivity of the sealing member and the maximum temperature of the driving IC chip;

FIG. 12A is a diagram showing a simulation result regarding the temperature in a case where a thickness of the thermal diffusion plate is set to 0.125 mm;

FIG. 12B is a diagram showing a simulation result regarding the temperature in a case where the thickness of the thermal diffusion plate is set to 0.5 mm;

FIG. 12C is a diagram showing a simulation result regarding the temperature in a case where the thickness of the thermal diffusion plate is set to 1 mm;

FIG. 13 is a graph showing a relationship between the thickness of the thermal diffusion plate and the maximum temperature of the driving IC chip;

FIG. 14A is a cross-sectional view showing a manufacturing process of the semiconductor device according to the first embodiment;

FIG. 14B is a cross-sectional view showing a manufacturing process of the semiconductor device following the manufacturing process shown in FIG. 14A;

FIG. 14C is a cross-sectional view showing a manufacturing process of the semiconductor device following the manufacturing process shown in FIG. 14B;

FIG. 14D is a cross-sectional view showing a manufacturing process of the semiconductor device following the manufacturing process shown in FIG. 14C;

FIG. 15 is a cross-sectional view of a semiconductor device according to a second embodiment;

FIG. 16A is a cross-sectional view showing a manufacturing process of the semiconductor device according to the second embodiment;

FIG. 16B is a cross-sectional view showing a manufacturing process of the semiconductor device following the manufacturing process shown in FIG. 16A;

FIG. 16C is a cross-sectional view showing a manufacturing process of the semiconductor device following the manufacturing process shown in FIG. 16B;

FIG. 16D is a cross-sectional view showing a manufacturing process of the semiconductor device following the manufacturing process shown in FIG. 16C;

FIG. 17 is a cross-sectional view of a semiconductor device according to a third embodiment;

FIG. 18 is a cross-sectional view of the semiconductor device according to the third embodiment; and

FIG. 19 is a plan view of the semiconductor device according to the third embodiment.

### DETAILED DESCRIPTION

Next, a relevant technology is described only for understanding the following embodiments. In a semiconductor device according to the relevant technology, a semiconductor chip in which a transistor and the like are formed is mounted on a lead frame. A wiring substrate is disposed on the lead frame so as to be separated from the semiconductor chip, and is electrically connected to the semiconductor chip. The semiconductor chip and the wiring substrate are integrally sealed with a sealing member made of a mold resin or the like.

In the semiconductor device described above, the heat generated in the semiconductor chip is transferred to the wiring substrate via the mold resin, so that the wiring substrate may be heated to a high temperature and the reliability of the wiring substrate may be reduced.

A semiconductor device according to an aspect of the present disclosure includes a semiconductor module, a wiring substrate, a sealing member, and a thermal diffusion plate. The semiconductor module includes a semiconductor chip in which a semiconductor element is disposed. The wiring substrate is electrically connected to the semiconductor module. The sealing member seals the semiconductor module and the wiring substrate. The thermal diffusion plate is disposed between the semiconductor module and the wiring substrate, and has a thermal conductivity that is higher than a thermal conductivity of the sealing member. The thermal diffusion plate has a plate shape and is disposed in the sealing member in a state where a plane direction of the thermal diffusion plate is along a direction intersecting an arrangement direction of the semiconductor module and the wiring substrate.

According to this configuration, the thermal diffusion plate is disposed between the semiconductor module including the semiconductor chip and the wiring substrate. Thus, the heat from the semiconductor chip can be radiated in the plane direction of the thermal diffusion plate by the thermal diffusion plate, and the wiring substrate can be restricted from becoming a high temperature. Therefore, it is possible to restrict a decrease in the reliability of the wiring substrate.

Hereinafter, embodiments of the present disclosure will be described with reference to the drawings. In the following embodiments, the same or equivalent parts are denoted by the same reference numerals.

### First Embodiment

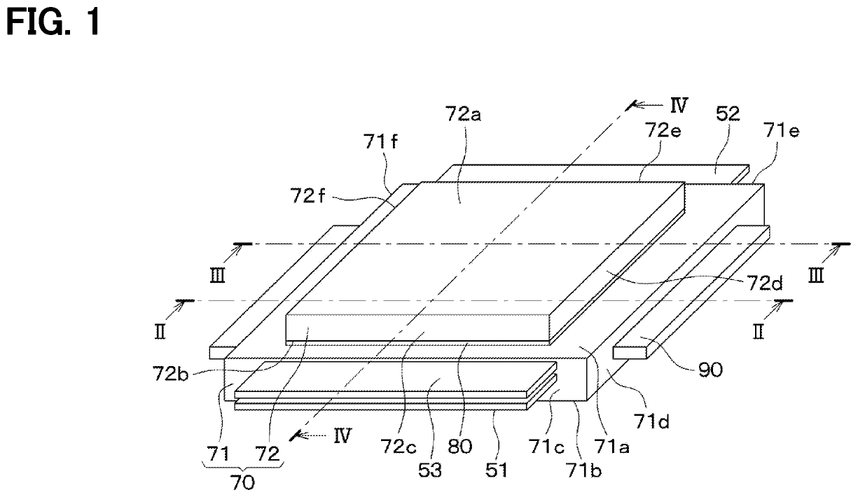

A configuration of a semiconductor device according to a first embodiment will be described with reference to FIGS. 1 to 6. The semiconductor device of the present embodiment is preferably mounted on a vehicle such as an automobile and used to drive various electronic devices for the vehicle. In the present embodiment, as will be described later, a so-called 2-in-1 package semiconductor device in which a first semiconductor chip 20 and a second semiconductor chip 30 are sealed with a sealing member 70 will be described.

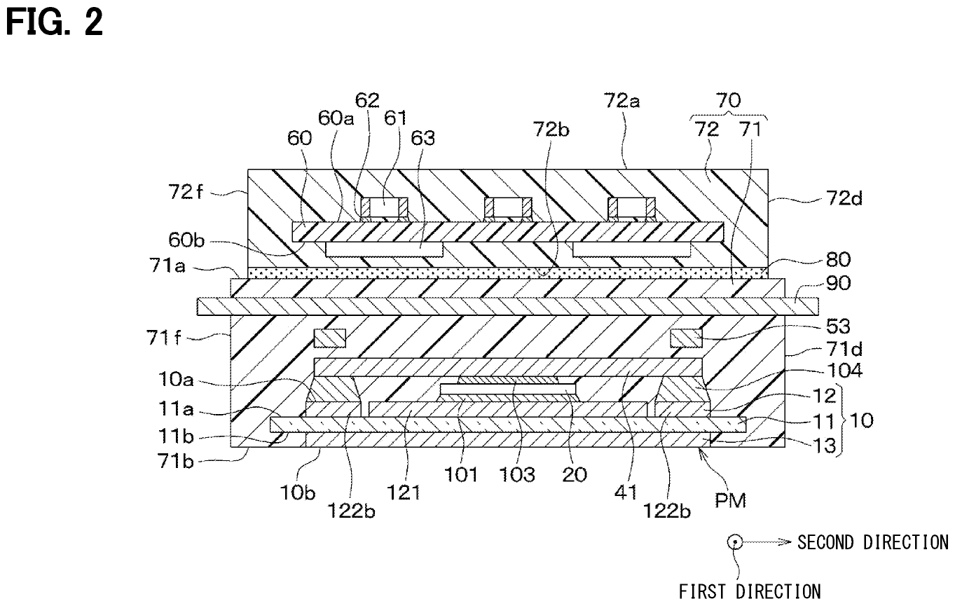

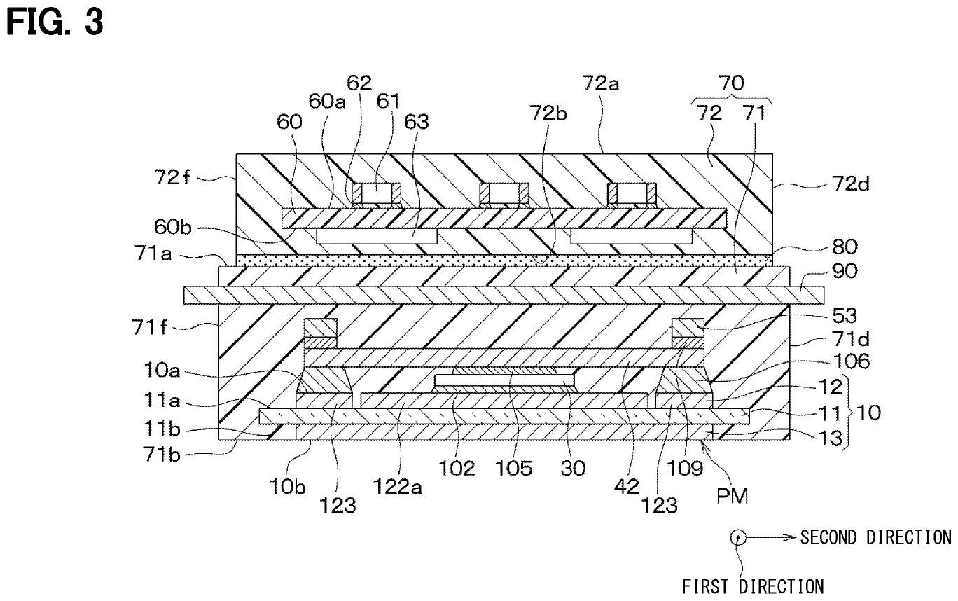

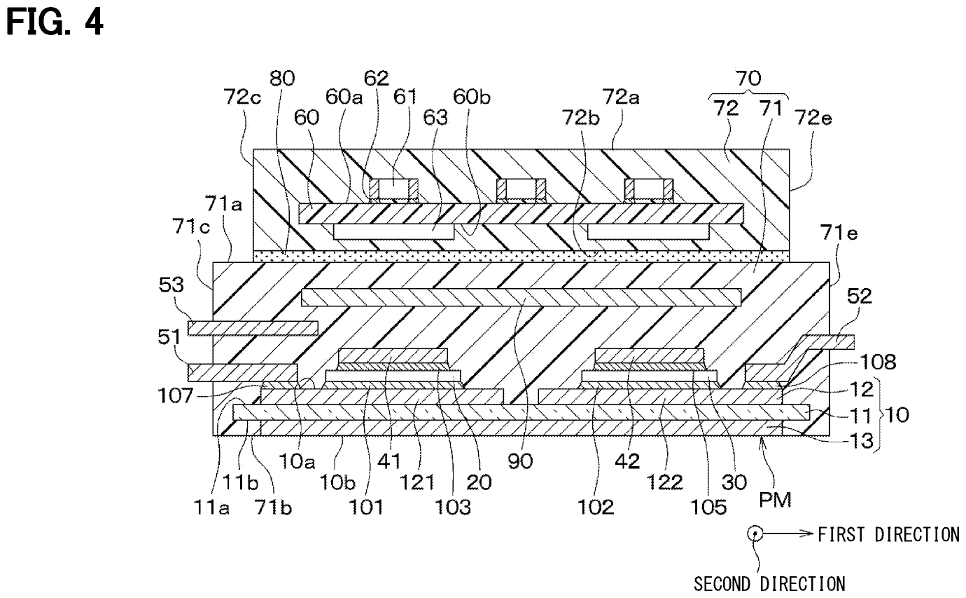

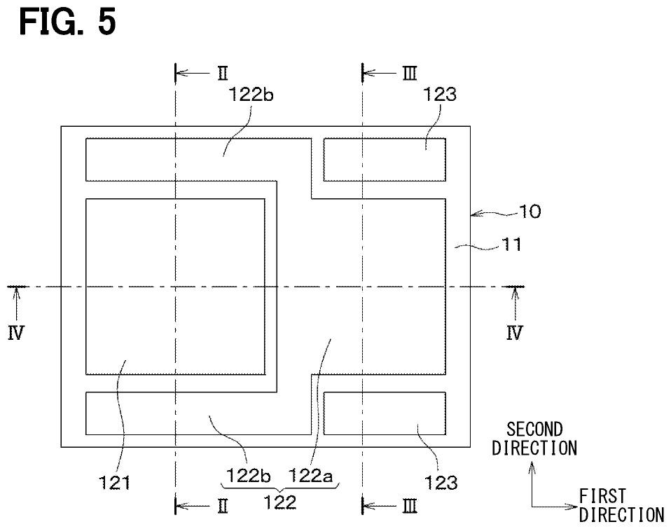

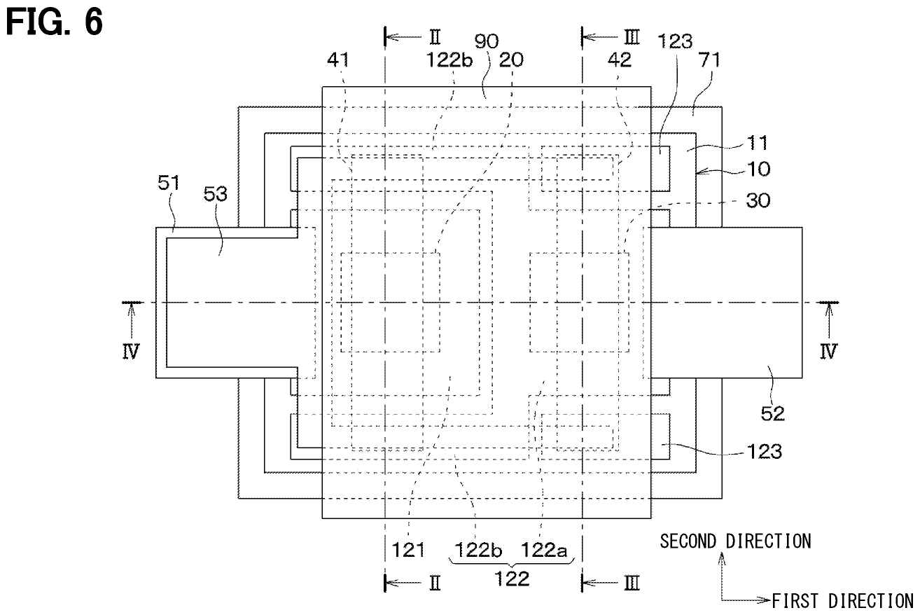

The semiconductor device of the present embodiment includes a support substrate 10, the first semiconductor chip 20, the second semiconductor chip 30, first and second coupling members 41 and 42, first to third connection terminals 51 to 53, and the sealing member 70. FIG. 2 is also a cross-sectional view of the semiconductor device taken along line II-II in FIGS. 5 and 6, FIG. 3 is also a cross-sectional view of the semiconductor device taken along line III-III in FIGS. 5 and 6, and FIG. 4 is also a cross-sectional view of the semiconductor device taken along line IV-IV in FIGS. 5 and 6. In FIG. 6, only an outer shape of a first sealing member 71 is shown for easy understanding, and a thermal diffusion plate 90 disposed in the first sealing member 71 is shown by a solid line as described later.

In the present embodiment, the support substrate 10 is formed of an active metal brazing (AMB) substrate. Specifically, the support substrate 10 includes an insulating substrate 11 having a front surface 11a and a rear surface 11b, a first metal film 12 formed on the front surface 11a of the insulating substrate 11, and a second metal film 13 formed on the rear surface 11b of the insulating substrate 11. The insulating substrate 11 is made of ceramic or the like, and the first metal film 12 and the second metal film 13 are made of copper or the like. Hereinafter, a surface of the support substrate 10 located on the first metal film 12 is also referred to as a first surface 10a of the support substrate 10, and a surface of the support substrate 10 located on the second metal film 13 is also referred to as a second surface 10b of the support substrate 10.

In the present embodiment, the first metal film 12 is patterned into a predetermined shape. Specifically, as shown in FIG. 5, the first metal film 12 is divided into a first mounting portion 121 to which the first semiconductor chip 20 is mounted, a second mounting portion 122 to which the second semiconductor chip 30 is mounted, and connection portions 123. Hereinafter, one direction in a plane direction of the support substrate 10 will be described as a first direction, and a direction intersecting the first direction and along the plane direction of the support substrate 10 will be described as a second direction.

The first mounting portion 121 has a rectangular planar shape. The second mounting portion 122 includes a main portion 122a having a rectangular planar shape and disposed at a predetermined distance from the first mounting portion 121 in the first direction. The second mounting portion 122 further includes two auxiliary portions 122b extending from the main portion 122a and arranged to sandwich the first mounting portion 121 in the second direction. Two connection portions 123 are disposed so as to sandwich the first mounting portion 121 in the second direction.

Each of the first semiconductor chip 20 and the second semiconductor chip 30 includes a power element such as a metal oxide semiconductor field effect transistor (MOSFET) element or an insulated gate bipolar transistor (IGBT) element. As shown in FIGS. 2 to 4, the first semiconductor chip 20 is disposed to the first mounting portion 121 via a bonding member 101, and the second semiconductor chip 30 is disposed to the second mounting portion 122 via a bonding member 102. The second semiconductor chip 30 is disposed to the main portion 122a of the second mounting portion 122.

The first coupling member 41 is disposed to the first semiconductor chip 20 via a bonding member 103. Specifically, the first coupling member 41 has a length in the second direction longer than that of the first semiconductor chip 20, and is disposed such that both end portions in the second direction protrude from the first semiconductor chip 20. The end portions of the first coupling member 41 protruding from the first semiconductor chip 20 in the normal direction with respect to the plane direction of the support substrate 10 are electrically connected to the auxiliary portions 122b of the second mounting portion 122 via a bonding member 104. Hereinafter, the normal direction with respect to the plane direction of the support substrate 10 is also simply referred to as the normal direction.

The second coupling member 42 is disposed to the second semiconductor chip 30 via a bonding member 105. Specifically, the second coupling member 42 has a length in the second direction longer than that of the second semiconductor chip 30, and is disposed such that both end portions in the second direction protrude from the second semiconductor chip 30. The end portions of the second coupling member 42 protruding from the second semiconductor chip 30 in the normal direction are electrically connected to the connection portions 123 via a bonding member 106.

The first connection terminal 51 has a plate shape, is connected to the first mounting portion 121 via a bonding member 107, and is disposed to extend from the first mounting portion 121 along the first direction opposite to the main portion 122a of the second mounting portion 122.

The second connection terminal 52 has a plate shape, is connected to the main portion 122a of the second mounting portion 122 via a bonding member 108, and is disposed to extend from the second mounting portion 122 along the first direction opposite to the first mounting portion 121.

As shown in FIG. 3 and FIG. 6, the third connection terminal 53 has a plate shape, is connected to both end portions of the second coupling member 42 in the second direction via a bonding member 109, and is disposed to extend from the second coupling member 42 along the first direction opposite to the second connection terminal 52. Note that the first to third connection terminals 51 to 53 of the present embodiment are arranged so as to partially protrude from the sealing member 70 as described later. The third connection terminal 53 is disposed such that a portion exposed from the sealing member 70 overlaps the first connection terminal 51 in the normal direction. However, the first connection terminal 51 and the third connection terminal 53 are disposed apart from each other by a predetermined distance. In addition, the third connection terminal 53 of the present embodiment has a shape in which a portion facing the first semiconductor chip 20 and the second semiconductor chip 30 is opened.

Hereinafter, an integrated body of the support substrate 10, the first semiconductor chip 20, the second semiconductor chip 30, the first and second coupling members 41 and 42, and the first to third connection terminals 51 to 53 is also referred to as a power module PM. In the present embodiment, the power module PM corresponds to a semiconductor module. Each of the bonding members 101 to 109 is made of, for example, solder or a silver sintered body.

A wiring substrate 60 is configured by a printed circuit board or the like having a first surface 60a and a second surface 60b, and is disposed such that the second surface 60b faces the first semiconductor chip 20 and the second semiconductor chip 30. In the wiring substrate 60, electronic components 61 such as a chip capacitor or a resistor are mounted to the first surface 60a via a bonding member 62, and a driving IC chip 63 for driving the first semiconductor chip 20 and the second semiconductor chip 30 is mounted to the second surface 60b via a bonding member (not shown). The types and arrangement positions of members mounted to the first surface 60a and the second surface 60b of the wiring substrate 60 can be appropriately changed. The wiring substrate 60 is electrically connected to the first semiconductor chip 20 and the second semiconductor chip 30 in a cross section different from the cross sections shown in FIGS. 2 to 4.

The sealing member 70 is made of a molding resin, a potting resin, or the like, and is configured to seal the support substrate 10, the first semiconductor chip 20, the second semiconductor chip 30, the first and second coupling members 41 and 42, the first to third connection terminals 51 to 53, the wiring substrate 60, and the like.

In the present embodiment, the sealing member 70 includes a first sealing member 71 that seals the support substrate 10, the first semiconductor chip 20, the second semiconductor chip 30, the first and second coupling members 41 and 42, the first to third connection terminals 51 to 53, and the like, and a second sealing member 72 that seals the wiring substrate 60 and the like.

More specifically, the first sealing member 71 has a substantially rectangular parallelepiped shape having a first surface 71a, a second surface 71b opposite to the first surface 71a, and four side surfaces 71c to 71f. In the present embodiment, a pair of side surfaces having the first direction as a normal direction will be described as a first side surface 71c and a third side surface 71e, and a pair of side surfaces having the second direction as a normal direction will be described as a second side surface 71d and a fourth side surface 71f.

The first sealing member 71 is configured such that the second surface 10b of the support substrate 10 is exposed from the second surface 71b. The first sealing member 71 is disposed such that portions of the first and third connection terminals 51 and 53 protrude from the first side surface 71c. The first sealing member 71 is configured such that a part of the second connection terminal 52 protrudes from the third side surface 71e.

The second sealing member 72 has a substantially rectangular parallelepiped shape having a first surface 72a, a second surface 72b opposite to the first surface 72a, and four side surfaces 72c to 72f. The wiring substrate 60 is disposed in the second sealing member 72 such that the first surface 60a is substantially parallel to the first surface 72a of the second sealing member 72.

The first sealing member 71 and the second sealing member 72 are integrated by bonding the first surface 71a of the first sealing member 71 and the second surface 72b of the second sealing member 72 via a bonding layer 80 formed of underfill or the like.

The thermal diffusion plate 90 is made of a material having a higher thermal conductivity than the sealing member 70, has a plate shape, and is disposed between the power module PM (that is, the first semiconductor chip 20 and the second semiconductor chip 30) and the wiring substrate 60. In the present embodiment, the thermal diffusion plate 90 is disposed in the first sealing member 71. The thermal diffusion plate 90 is disposed so as to partially protrude from the second side surface 71d and the fourth side surface 71f of the first sealing member 71, and is disposed so as not to protrude from the first side surface 71c and the third side surface 71e. That is, the thermal diffusion plate 90 is disposed so as to protrude from the second and fourth side surfaces 71d and 71f of the first sealing member 71, which are different from the first side surface 71c from which the first and third connection terminals 51 and 53 protrude and the third side surface 71e from which the second connection terminal 52 protrudes.

The thermal diffusion plate 90 is disposed in a state of being insulated from the first semiconductor chip 20, the second semiconductor chip 30, the wiring substrate 60, and the like. As long as the thermal diffusion plate 90 is made of a material having a higher thermal conductivity than the sealing member 70 as described above, the detailed material can be appropriately changed. For example, the thermal diffusion plate 90 may be made of copper, aluminum, iron, an alloy thereof, or a laminated plate in which plate members made of these metal materials are laminated. In this case, since the thermal diffusion plate 90 is made of a magnetic material such as iron, the thermal diffusion plate 90 functions as an electromagnetic shield, and propagation of noise between the power module PM and the wiring substrate 60 can also be restricted. The thermal diffusion plate 90 is made of, for example, graphite having a higher thermal conductivity in a plane direction than in a thickness direction. Graphite has a thermal conductivity of 7 W/mK in the thickness direction and a thermal conductivity of 1700 W/mK in the plane direction. The thermal diffusion plate 90 may also be made of, for example, an insulating material such as ceramic.

The configuration of the semiconductor device according to the present embodiment has been described above. Next, the operation of the semiconductor device will be described, and the configuration of the thermal diffusion plate 90 will be described in more detail.

The semiconductor device as described above is used to constitute, for example, an inverter circuit, and the first semiconductor chip 20 and the second semiconductor chip 30 generate heat during use. When the wiring substrate 60 reaches a high temperature due to heat transfer from the first semiconductor chip 20 and the second semiconductor chip 30, the reliability of the wiring substrate 60 decreases. However, in the present embodiment, the thermal diffusion plate 90 is disposed between the first semiconductor chip 20 and the second semiconductor chip 30. Thus, the thermal diffusion plate 90 can spread the heat from the first semiconductor chip 20 and the second semiconductor chip 30 in the plane direction of the thermal diffusion plate 90, and can restrict the wiring substrate 60 from reaching a high temperature.

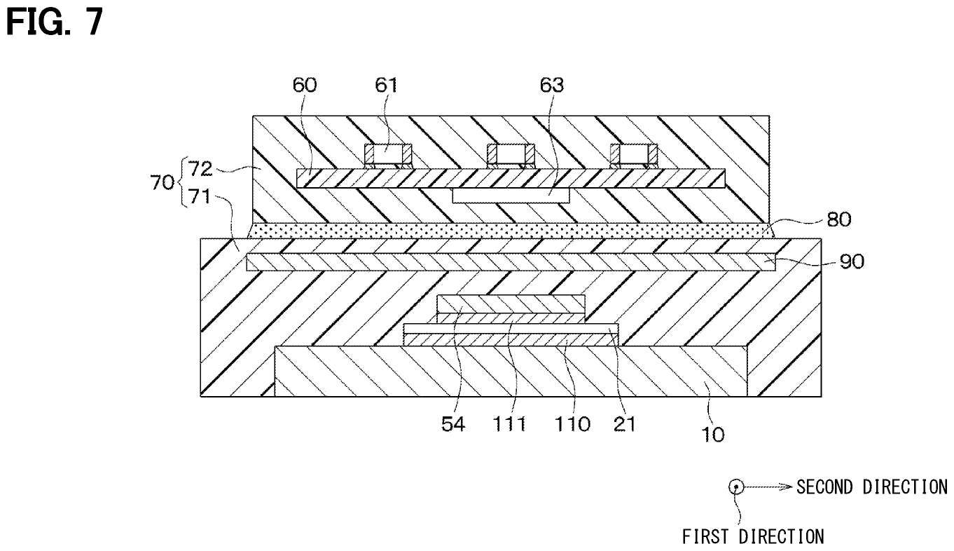

The present inventors performed a simulation using a semiconductor device of FIG. 7, which is a simplified model of the above-described semiconductor device. In the semiconductor device of FIG. 7, a semiconductor chip 21 is disposed to a support substrate 10 via a bonding member 110, and a connection terminal 54 is disposed to the semiconductor chip 21 via a bonding member 111. Furthermore, in the semiconductor device shown in FIG. 7, a thermal diffusion plate 90 is disposed above the connection terminal 54 in a state of being separated from the connection terminal 54, and the wiring substrate 60 provided with the electronic components 61 and the driving IC chip 63 is disposed above the thermal diffusion plate 90. The sealing member 70 is disposed so as to seal these components. Specifically, the support substrate 10, the semiconductor chip 21, and the thermal diffusion plate 90 are sealed with the first sealing member 71, and the wiring substrate 60 is sealed with the second sealing member 72. The semiconductor device is configured by bonding the first sealing member 71 and the second sealing member 72 via the bonding layer 80.

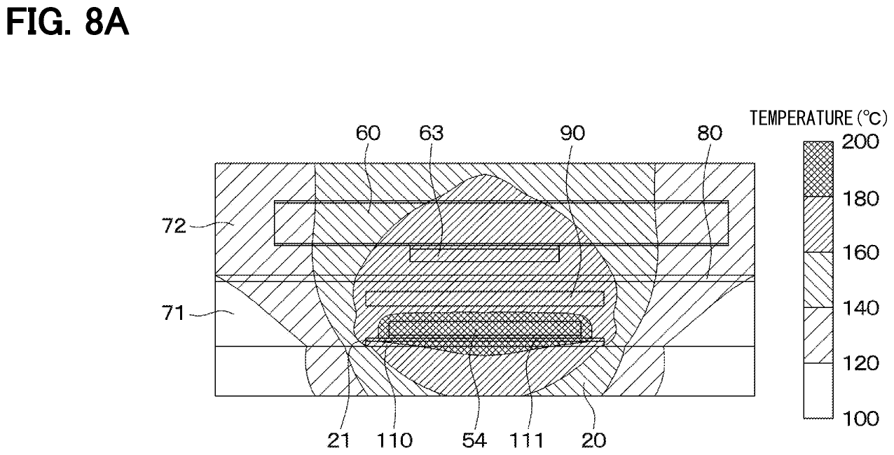

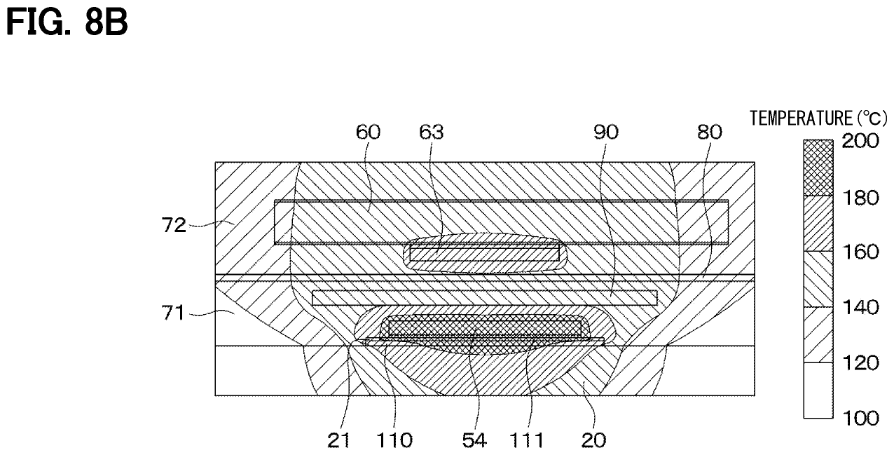

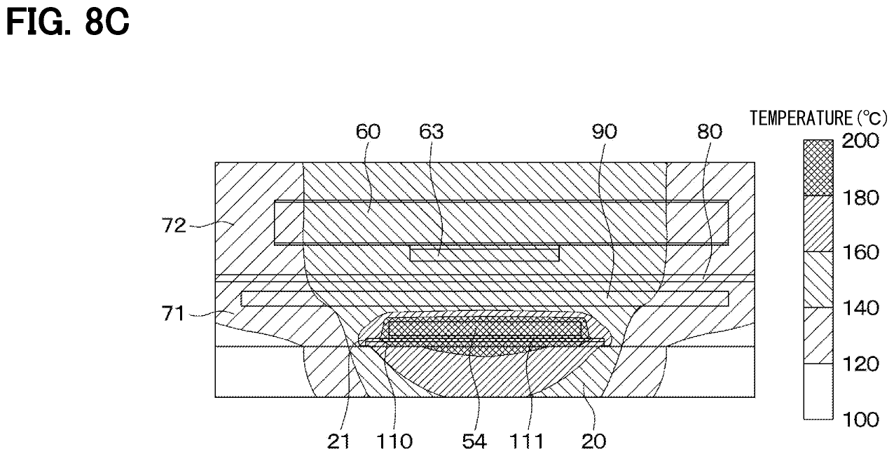

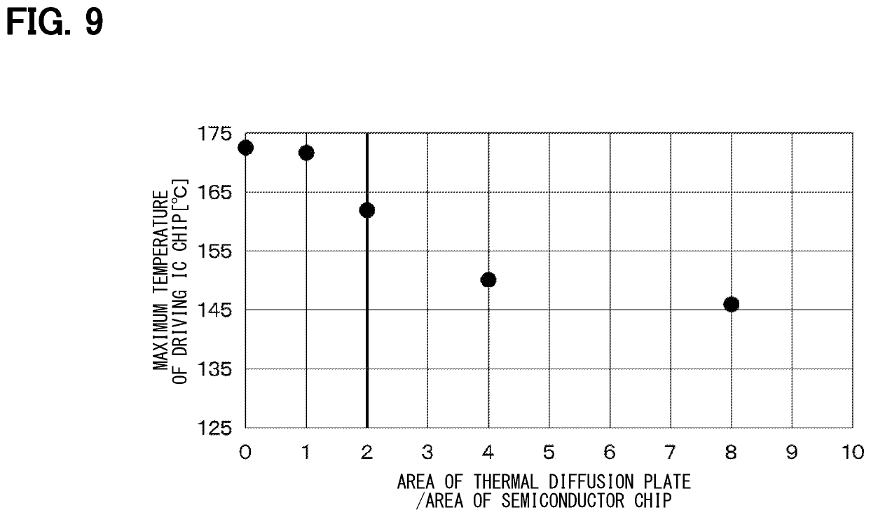

The present inventors have diligently studied the configuration of thermal diffusion plate 90 using the above-described semiconductor device, and obtained the results shown in FIGS. 8A to 8C, 9, 10A, 10B, 11, 12A to 12C, and 13. Each figure shows the result when the semiconductor chip 21 is set at 200° C. The temperatures in FIGS. 9, 11, and 13 indicate the temperature of the driving IC chip 63.

First, the present inventors diligently studied an area of the thermal diffusion plate 90 and obtained the results shown in FIGS. 8A to 8C and FIG. 9. Here, the area refers to an area of a surface whose plane direction intersects an arrangement direction of the semiconductor chip 21 and the thermal diffusion plate 90. In other words, the area here is the area of a surface whose normal direction is the arrangement direction of the semiconductor chip 21 and the thermal diffusion plate 90. FIGS. 8A to 8C and 9 show the results in a case where the thermal conductivity of the sealing member 70 is 0.9 W/mK, the thermal diffusion plate 90 is made of copper (that is, the thermal conductivity is 398 W/mK), and the thickness of thermal diffusion plate 90 is 0.5 mm.

As shown in FIGS. 8A to 8C and 9, it is confirmed that the temperature of the driving IC chip 63 can be lowered with an increase in the area of the thermal diffusion plate 90. Then, it is confirmed that the temperature of the driving IC chip 63 sharply decreases when the area of the thermal diffusion plate 90 is twice or more of the area of the semiconductor chip 21. Therefore, it is preferable that the area of the thermal diffusion plate 90 is twice or more of the area of the semiconductor chip 21. When multiple semiconductor chips such as the first semiconductor chip 20 and the second semiconductor chip 30 are provided as in the present embodiment, the area of the thermal diffusion plate 90 is preferably twice or more of the total area of the multiple semiconductor chips.

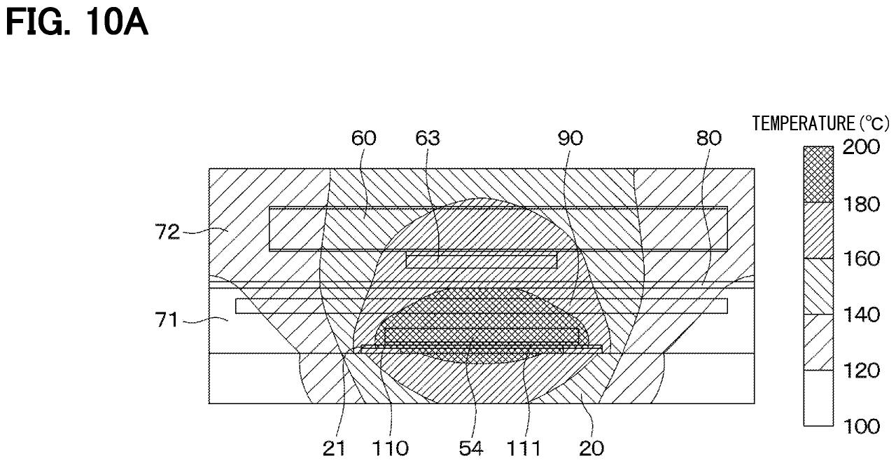

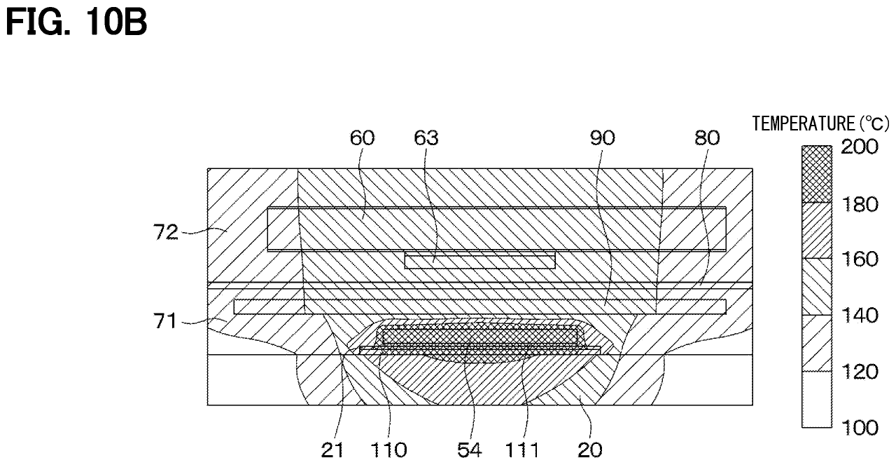

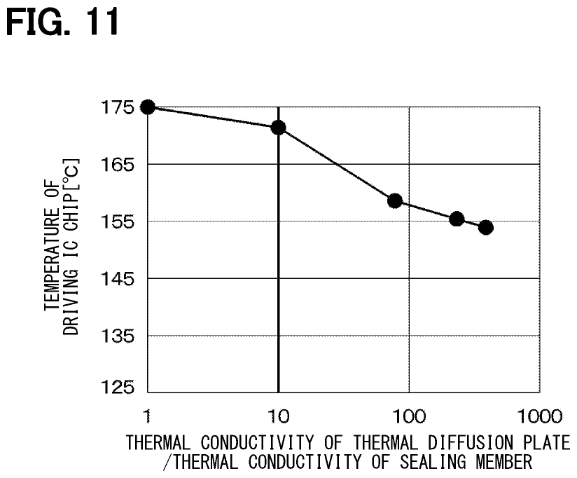

In addition, the present inventors have diligently studied the thermal conductivity of thermal diffusion plate 90 and obtained the results shown in FIGS. 10A, 10B, and 11. FIGS. 10A, 10B, and 11 show the results when in a case where the thermal conductivity of the sealing member 70 is 0.9 W/mK, the thickness of the thermal diffusion plate 90 is 0.5 mm, and the area of the thermal diffusion plate 90 is four times the area of the semiconductor chip 21. FIG. 10B shows a simulation result when the thermal diffusion plate 90 is made of copper (that is, the thermal conductivity is 398 W/mK) and the thermal conductivity of the thermal diffusion plate 90 is about 442 times the thermal conductivity of the sealing member 70.

As shown in FIGS. 10A, 10B, and 11, it is confirmed that the temperature of the driving IC chip 63 can be lowered with an increase in the thermal conductivity of the thermal diffusion plate 90. In addition, it is confirmed that the temperature of the driving IC chip 63 sharply decreases when the thermal conductivity of the thermal diffusion plate 90 is 10 times or more of the thermal conductivity of the sealing member 70. Therefore, the thermal conductivity of the thermal diffusion plate 90 is preferably 10 times or more of the thermal conductivity of the semiconductor chip 21.

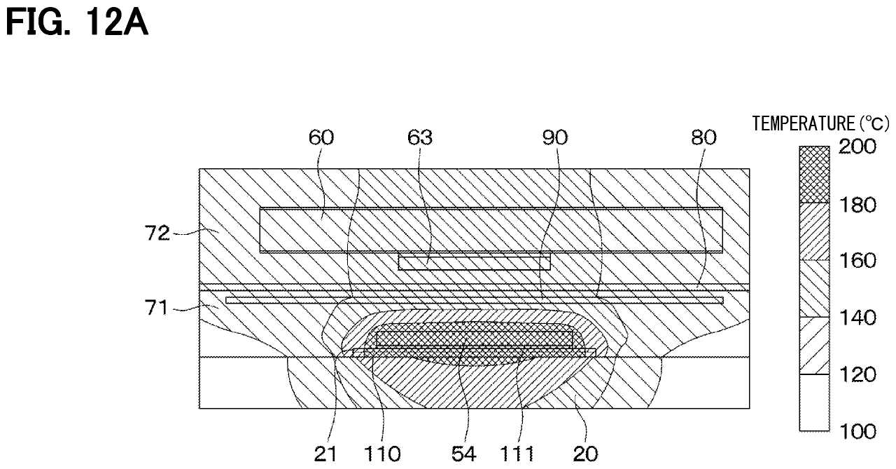

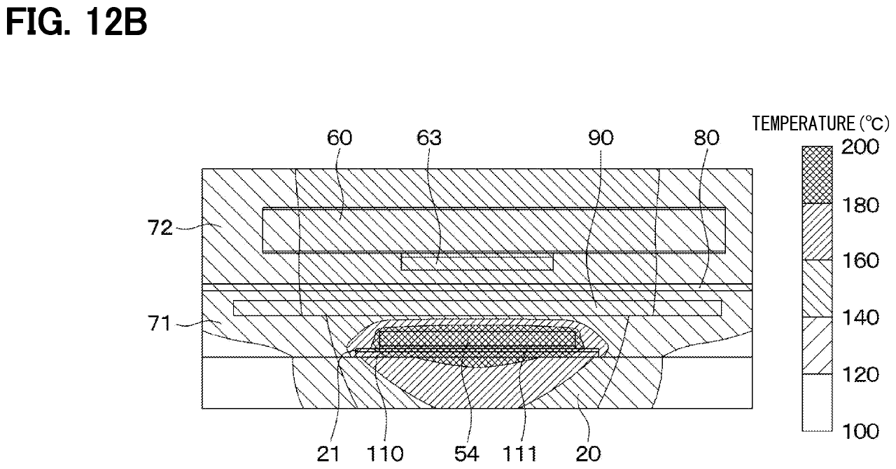

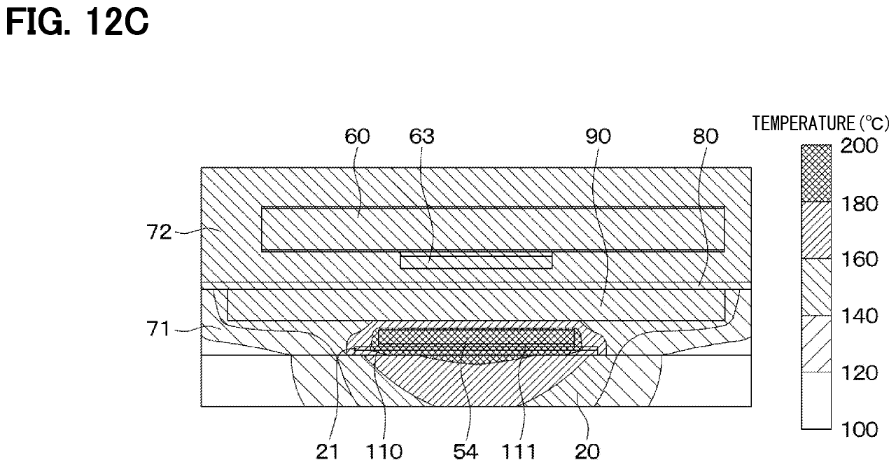

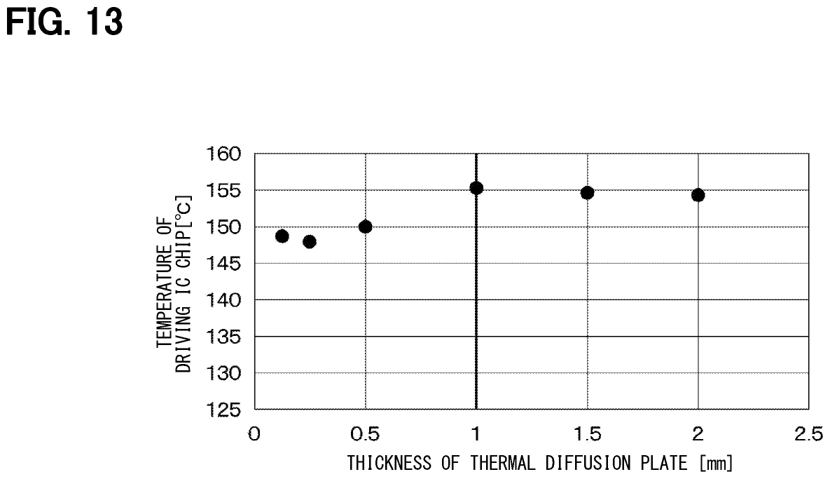

Furthermore, the present inventors diligently studied the thickness of the thermal diffusion plate 90 and obtained the results shown in FIGS. 12A to 12C and FIG. 13. Note that FIGS. 12A to 12C and FIG. 13 show the results in a case where the thermal conductivity of the sealing member 70 is 0.9 W/mK, the thermal diffusion plate 90 is made of copper (that is, the thermal conductivity is 398 W/mK), and the area of the thermal diffusion plate 90 is four times the area of the semiconductor chip 21.

As shown in FIGS. 12A to 12C and FIG. 13, it is confirmed that the temperature of the driving IC chip 63 can be lowered with a decrease in the thickness of the thermal diffusion plate 90. Then, it is confirmed that the temperature of the driving IC chip 63 sharply decreases when the thickness of the thermal diffusion plate 90 is 1 mm or less. Therefore, the thickness of the thermal diffusion plate 90 is preferably 1 mm or less. When the thickness of the thermal diffusion plate 90 is in a range of 1 mm or more, it is confirmed that the heat transfer in the thickness direction also increases and the effect decreases. However, for example, as shown in FIG. 9, when the thermal diffusion plate 90 is not provided, the temperature of the driving IC chip 63 becomes about 173° C. The case where the thermal diffusion plate 90 is not provided is a case where the area of the thermal diffusion plate/the area of the semiconductor chip is 0 in FIG. 9. Therefore, it is confirmed that the temperature of the driving IC chip 63 can be lowered by providing the thermal diffusion plate 90, although the effect is reduced when the thermal diffusion plate 90 is too thick.

From the above, it is preferable that the area of the thermal diffusion plate 90 is twice or more of the total area of the first semiconductor chip 20 and the second semiconductor chip 30. It is preferable that the thermal conductivity of the thermal diffusion plate 90 is 10 times or more of the thermal conductivity of the sealing member 70. It is preferable that the thermal diffusion plate 90 has a thickness of 1 mm or less.

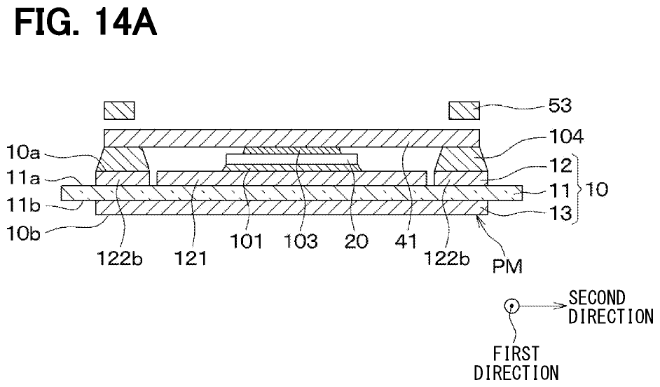

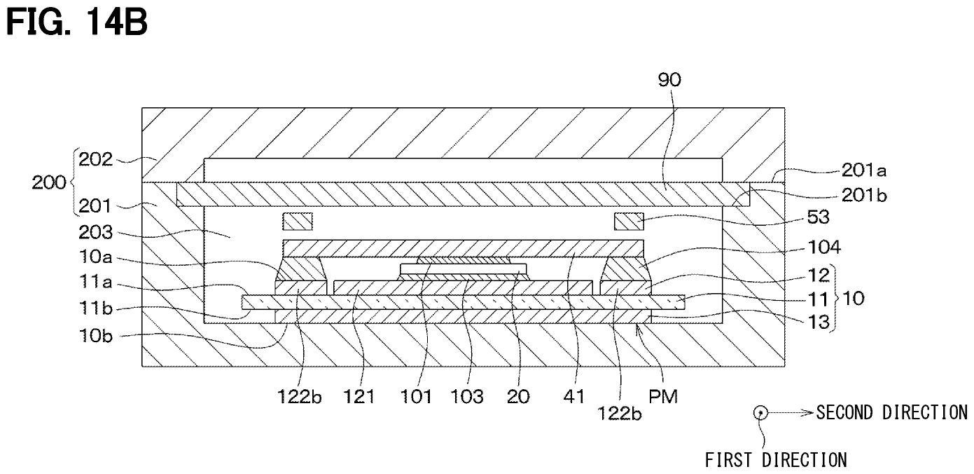

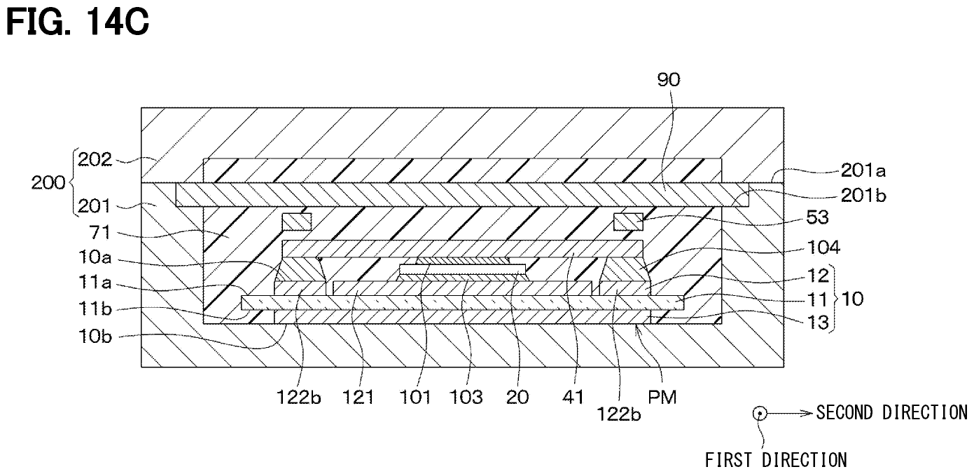

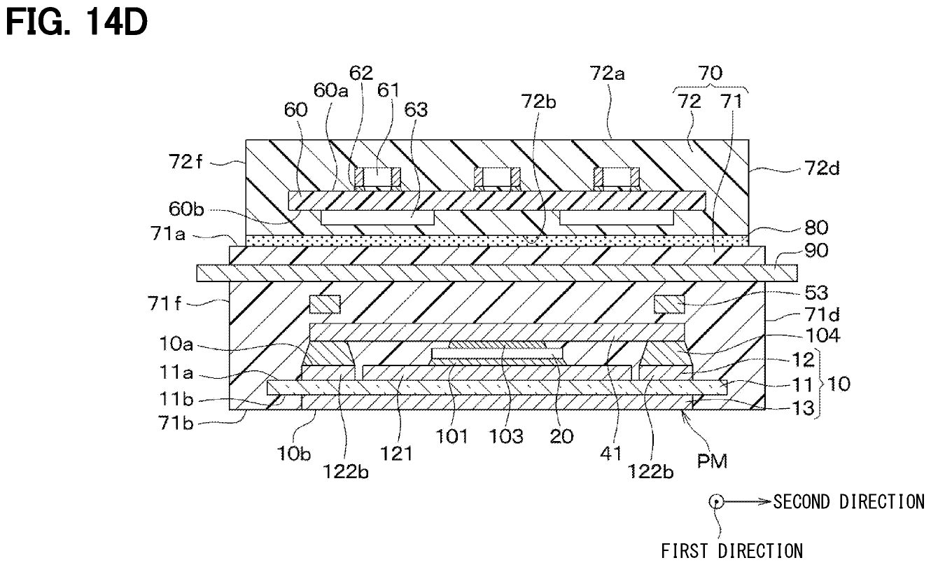

The configuration of the semiconductor device according to the present embodiment has been described above. Next, a method of manufacturing the semiconductor device of the present embodiment will be described with reference to FIGS. 14A to 14D. Each of FIGS. 14A to 14D shows a cross section corresponding to the cross section shown in FIG. 2.

First, as shown in FIG. 14A, the power module PM is prepared in which the first semiconductor chip 20 and the second semiconductor chip 30 are disposed above the support substrate 10, and the first to third connection terminals 51 to 53 and the first and second coupling members 41 and 42 are disposed. The second semiconductor chip 30 and the second coupling member 42 are arranged in a cross section different from that of FIG. 14A.

Subsequently, as shown in FIG. 14B, a mold 200 in which a cavity 203 is formed by fitting a first mold 201 and a second mold 202 is prepared, and the power module PM and the thermal diffusion plate 90 are disposed in the mold 200. In the present embodiment, the first mold 201 has a recessed portion 201b at an inner portion of a surface 201a fitted to the second mold 202. The inner portion of the surface 201a is a portion close to the cavity 203. The recessed portion 201b has a depth corresponding to the thickness of the thermal diffusion plate 90.

Then, the power module PM is disposed in the first mold 201 such that the second surface 10b of the support substrate 10 is in contact with the first mold 201. In addition, the thermal diffusion plate 90 is disposed such that an outer edge portion of the thermal diffusion plate 90 is fitted into the recessed portion 201b of the first mold 201. The thermal diffusion plate 90 is sandwiched between the first mold 201 and the second mold 202 by fitting the first mold 201 and the second mold 202.

Subsequently, as shown in FIG. 14C, a molten resin is poured into the mold 200 and solidified to form the first sealing member 71. Accordingly, the first sealing member 71 in which a part of the thermal diffusion plate 90 protrudes is formed.

Although not particularly illustrated, the second sealing member 72 in which the wiring substrate 60 is disposed is prepared. Then, as shown in FIG. 14D, the semiconductor device is formed by bonding the first sealing member 71 and the second sealing member 72 via the bonding layer 80.

According to the present embodiment described above, the thermal diffusion plate 90 is disposed between the wiring substrate 60 and the power module PM having the first semiconductor chip 20 and the second semiconductor chip 30. Thus, the heat from the first semiconductor chip 20 and the second semiconductor chip 30 can be radiated in the plane direction of the thermal diffusion plate 90 by the thermal diffusion plate 90, and the wiring substrate 60 can be restricted from reaching a high temperature. Therefore, it is possible to restrict a decrease in the reliability of the wiring substrate 60.

In recent years, it has also been considered to form the first semiconductor chip 20 and the second semiconductor chip 30 using a silicon carbide substrate in order to reduce loss. In this case, since silicon carbide is a wide gap material, a semiconductor chip formed using the silicon carbide substrate has a use limit temperature of 200° C., for example. For example, when the semiconductor chip is formed using a silicon substrate, the use limit temperature is 150° C., for example. Therefore, by disposing the thermal diffusion plate 90 as in the present embodiment, even when the first semiconductor chip 20 and the second semiconductor chip 30 are formed of the silicon carbide substrate or the like and tend to reach a high temperature, it is possible to sufficiently restrict the wiring substrate 60 from reaching a high temperature. In other words, even when the first semiconductor chip 20 and the second semiconductor chip 30 are formed of the silicon carbide substrate or the like, it is not necessary to perform a special process on the wiring substrate 60, and the same wiring substrate as that of the conventional art can be used as the wiring substrate 60.

In the present embodiment, the sealing member 70 is formed by bonding the first sealing member 71 and the second sealing member 72. Therefore, the first sealing member 71 and the second sealing member 72 may be separately prepared, and the design of each of the sealing members 71 and 72 can be easily changed.

In the present embodiment, the thermal diffusion plate 90 has the area twice or more of the total area of the first semiconductor chip 20 and the second semiconductor chip 30, so that the wiring substrate 60 can be sufficiently restricted from reaching a high temperature.

In the present embodiment, the thermal conductivity of the thermal diffusion plate 90 is 10 times or more of the thermal conductivity of the sealing member 70, so that the wiring substrate 60 can be sufficiently restricted from reaching a high temperature.

In the present embodiment, since the thickness of the thermal diffusion plate 90 is 1 mm or less, it is possible to sufficiently restrict the wiring substrate 60 from reaching a high temperature.

In the present embodiment, since the thermal diffusion plate 90 is made of graphite or the like having a higher thermal conductivity in the plane direction than in the thickness direction, the wiring substrate 60 can be further restricted from reaching a high temperature.

In the present embodiment, the thermal diffusion plate 90 is disposed so as to be exposed from the first sealing member 71. Therefore, the first sealing member 71 can be easily disposed using the mold 200 or the like.

In the present embodiment, the thermal diffusion plate 90 is disposed so as to protrude from a surface different from the surface on which the first to third connection terminals 51 to 53 protrude from the first sealing member 71. Therefore, a creepage distance can be easily secured as compared with a case where the surfaces of the first sealing member 7 from which the first to third connection terminals 51 to 53 protrude are the same as the surfaces of the first sealing member 7 from which the thermal diffusion plate 90 protrudes.

In the present embodiment, the thermal diffusion plate 90 is insulated from the first semiconductor chip 20, the second semiconductor chip 30, the wiring substrate 60, and the like. Therefore, no current flows through the thermal diffusion plate 90, and heat generation of the thermal diffusion plate 90 can be restricted. Therefore, the wiring substrate 60 can be restricted from reaching a high temperature by the heat of the thermal diffusion plate 90.

### Second Embodiment

The following describes a second embodiment. The present embodiment is different from the first embodiment in the configuration of the sealing member 70. The other configurations of the present embodiment are similar to those of the first embodiment, and therefore a description of the similar configurations will not be repeated.

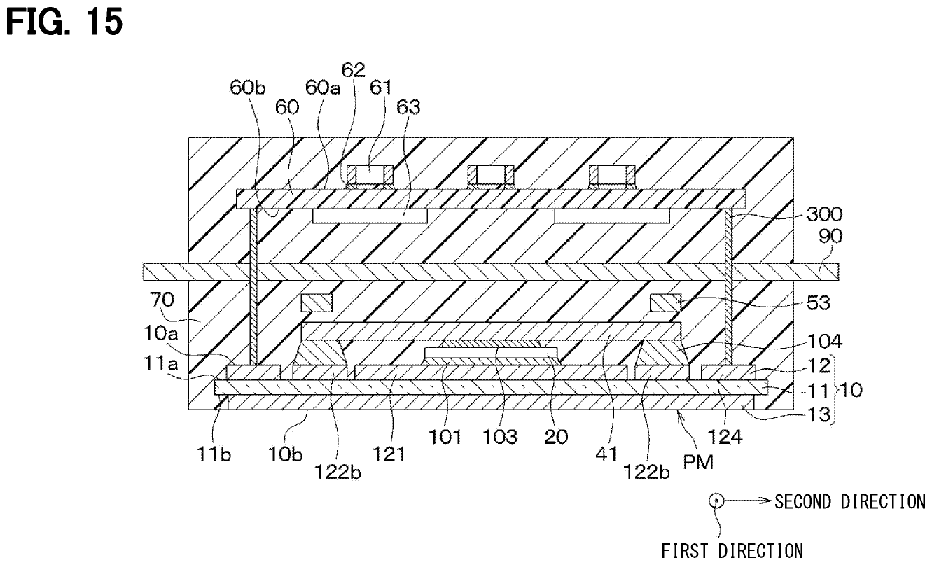

In the semiconductor device of the present embodiment, as shown in FIG. 15, the sealing member 70 is formed so as to integrally seal the power module PM, the wiring substrate 60, and the thermal diffusion plate 90. Specifically, the first metal film 12 of the support substrate 10 includes fixing portions 124. The fixing portions 124 are apart from the first mounting portion 121, the second mounting portion 122, and the connecting portions 123, and are not electrically connected to any of the first mounting portion 121, the second mounting portion 122, and the connecting portions 123. The fixing portions 124 are formed at four corners on the first surface 10a of the support substrate 10.

The wiring substrate 60 is mechanically connected to the support substrate 10 via support portions 300 connected to the fixing portions 124. In the present embodiment, the support portions 300 are connected to four corners of the second surface 60b of the wiring substrate 60. The support portions 300 are formed by, for example, appropriately bending a copper plate.

The length of the thermal diffusion plate 90 in the first direction is shorter than the interval between the support portions 300 adjacent to each other in the first direction. The thermal diffusion plate 90 is disposed at a position between the support portions 300 adjacent to each other in the first direction.

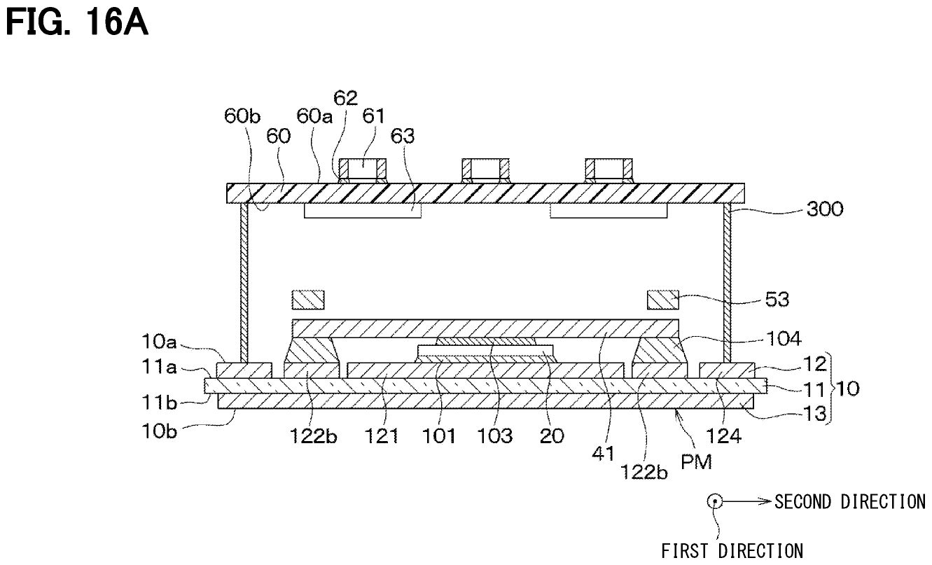

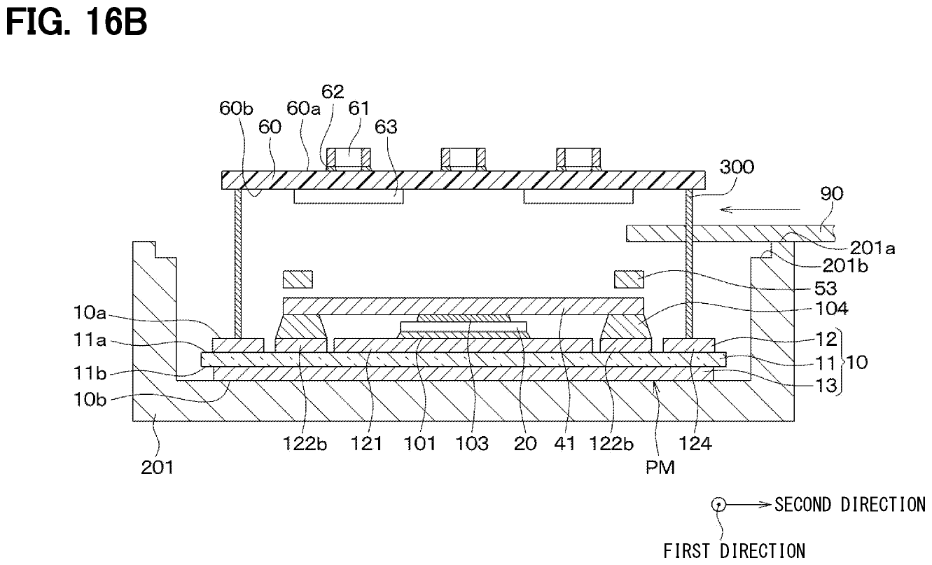

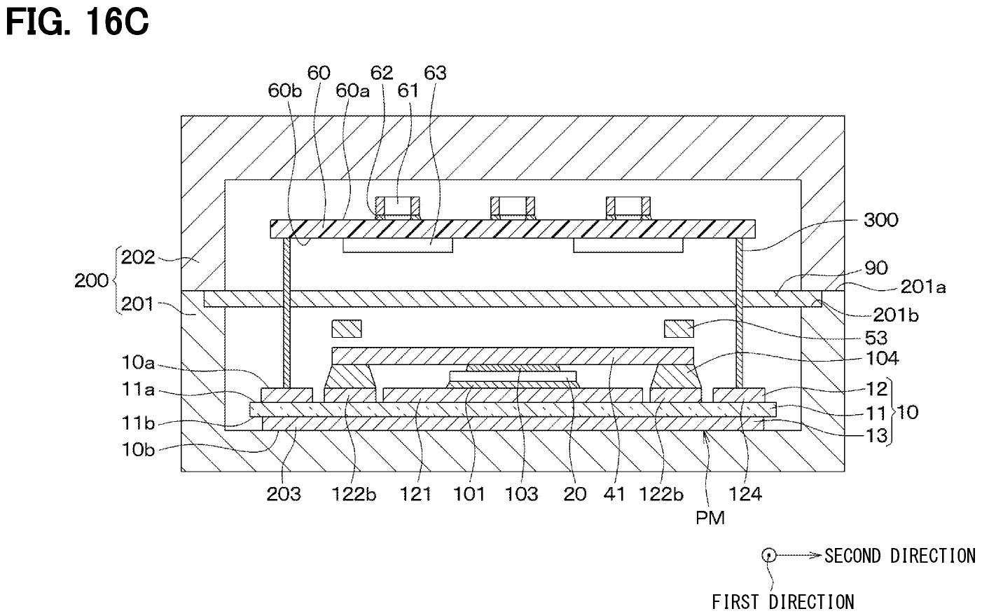

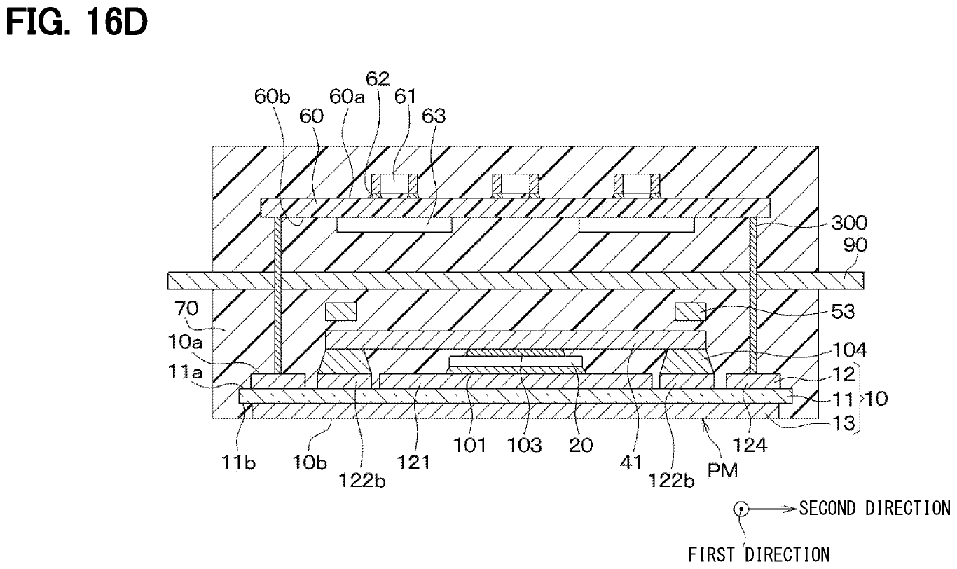

The configuration of the semiconductor device according to the present embodiment has been described above. Next, a method of manufacturing the semiconductor device will be described with reference to FIGS. 16A to 16D.

First, as shown in FIG. 16A, the wiring substrate 60 is bonded to the power module PM via the support portions 300.

Next, as shown in FIG. 16B, the power module PM and the thermal diffusion plate 90 are disposed in the mold 200. As described above, the length of the thermal diffusion plate 90 in the first direction is shorter than the interval between the support portions 300 adjacent to each other in the first direction. Therefore, the thermal diffusion plate 90 is slid in the second direction so as to pass between the support portions 300 adjacent to each other in the first direction, and the thermal diffusion plate 90 is disposed so that the outer edge portion of the thermal diffusion plate 90 is fitted into the recessed portion 201b of the first mold 201.

Next, as shown in FIG. 16C, the first mold 201 and the second mold 202 are fitted to each other, thereby sandwiching the thermal diffusion plate 90 between the first mold 201 and the second mold 202.

Thereafter, as shown in FIG. 16D, a molten resin is poured into the mold 200 and solidified to form the sealing member 70, thereby manufacturing the semiconductor device.

According to the present embodiment described above, since the thermal diffusion plate 90 is disposed between the wiring substrate 60 and the power module PM having the first semiconductor chip 20 and the second semiconductor chip 30, the same effects as those of the first embodiment can be obtained.

In the present embodiment, the power module PM and the wiring substrate 100 are fixed via the support portions 300, and the sealing member 70 is integrally formed so as to seal the power module PM, the wiring substrate 60, and the like. Therefore, the process of forming the sealing member 70 can be simplified.

### Third Embodiment

The following describes a third embodiment. The present embodiment is different from the first embodiment in the configuration of the third connection terminal 53. The other configurations of the present embodiment are similar to those of the first embodiment, and therefore a description of the similar configurations will not be repeated.

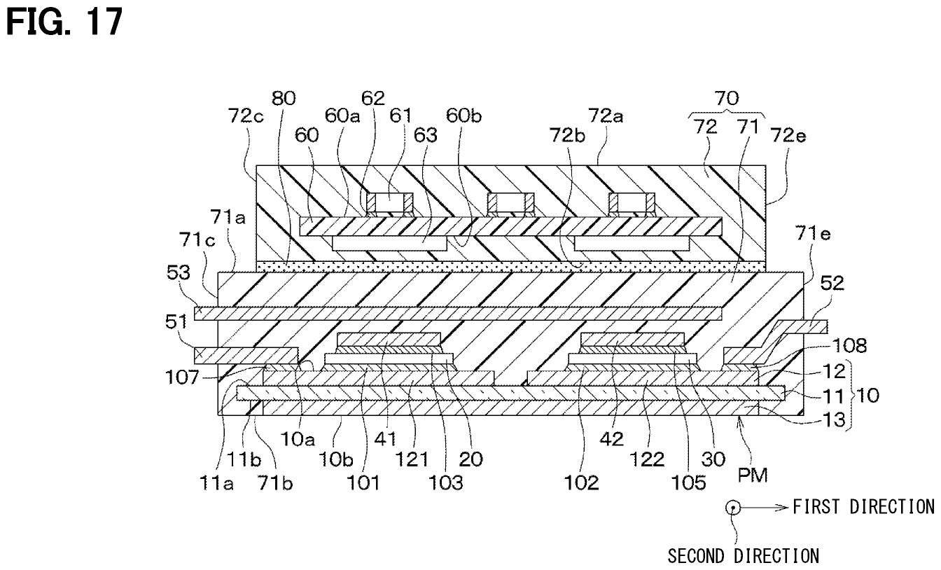

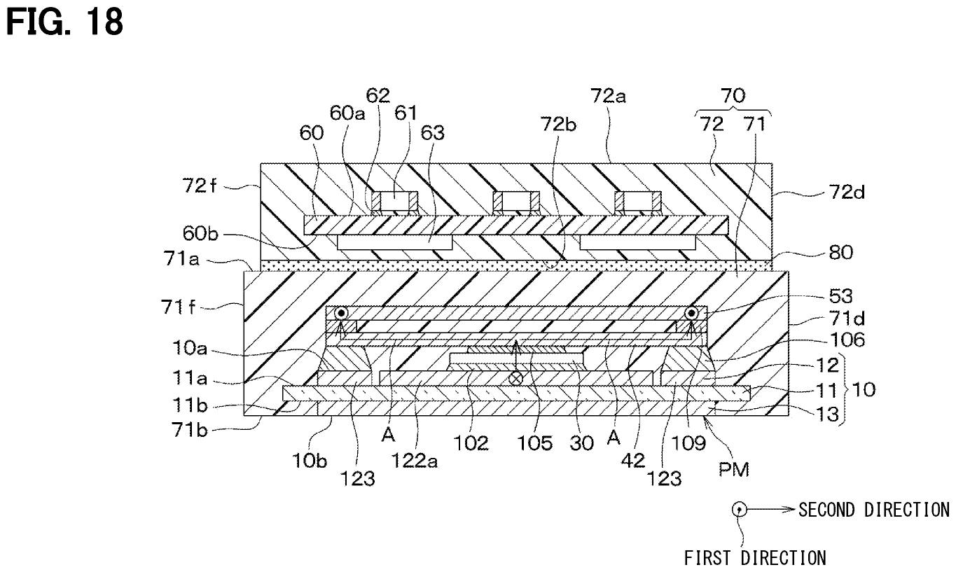

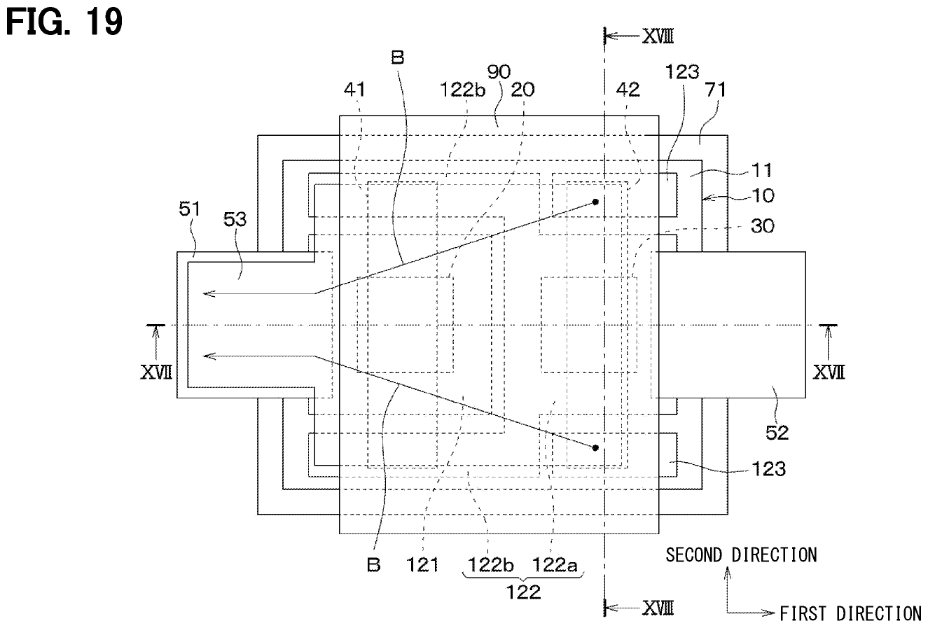

In the semiconductor device of the present embodiment, as shown in FIGS. 17 to 19, the third connection terminal 53 is also disposed at a position facing the first semiconductor chip 20 and the second semiconductor chip 30 in the normal direction. Therefore, in the present embodiment, the third connection terminal 53 also functions as a thermal diffusion plate. The thermal diffusion plate 90 in the first embodiment is not disposed. As in the first embodiment, the second coupling member 42 is connected to the support substrate 10 via the bonding member 106. Therefore, the third connection terminal 53 (that is, the thermal diffusion plate) is thermally connected to the support substrate 10 via the second coupling member 42. In addition, since the thermal diffusion plate of the present embodiment is formed of the third connection terminal 53, the thermal diffusion plate is formed of a material having conductivity. FIG. 17 is a cross-sectional view of the semiconductor device taken along line XVII-XVII in FIG. 19, and FIG. 18 is a cross-sectional view of the semiconductor device taken along line XVIII-XVIII in FIG. 19.

According to the present embodiment described above, the third connection terminal 53 functioning as the thermal diffusion plate 90 is disposed between the wiring substrate 60 and the power module PM including the first semiconductor chip 20 and the second semiconductor chip 30. Therefore, effects similar to those of the first embodiment can be obtained.

In the present embodiment, the third connection terminal 53 is also disposed at a position facing the first semiconductor chip 20 and the second semiconductor chip 30 in the normal direction, and also functions as a thermal diffusion plate. Unlike the first embodiment, the thermal diffusion plate 90 formed of a member different from the third connection terminal 53 is not disposed. Therefore, since a space for disposing the thermal diffusion plate 90 in the first embodiment is not required, the thickness of the first sealing member 71 in the normal direction can be reduced, and the size of the semiconductor device can be reduced. Furthermore, since the thermal diffusion plate 90 different from the third connection terminal 53 is not required, the number of components can be reduced.

In the present embodiment, the third connection terminal 53 is connected to both end portions of the second coupling member 42 in the second direction via the bonding member 109. The third connection terminal 53 is drawn out so as to be exposed from the first side surface 71c. Therefore, first, as indicated by arrows A in FIG. 18, in the third connection terminal 53, currents flow to portions connected to both end portions of the second coupling member 42 in the second direction via the main portion 122a of the second mounting portion 122 and the second semiconductor chip 30. As indicated by arrows B in FIG. 19, the currents flowing through the third connection terminal 53 tend to flow linearly from the joint portions with the second coupling member 42 to the portion protruding from the first sealing member 71. Therefore, a portion of the third connection terminal 53 facing the first semiconductor chip 20 and a portion of the third connection terminal 53 facing the second semiconductor chip 30 are portions through which a current hardly flows. Therefore, the portions of the third connection terminal 53 facing the first semiconductor chip 20 and the second semiconductor chip 30 can be restricted from being heated to a high temperature by the current. Therefore, heat from the first semiconductor chip 20 and the second semiconductor chip 30 can be effectively absorbed.

In the present embodiment, the third connection terminal 53 is also connected to the connection portions 123 of the support substrate 10 via the second coupling member 42. That is, the third connection terminal 53 is thermally connected to the support substrate 10. Thus, it is also possible to release heat from the third connection terminal 53 to the support substrate 10, and it is possible to restrict the third connection terminal 53 from reaching a high temperature. Therefore, heat from the first semiconductor chip 20 and the second semiconductor chip 30 can be more effectively absorbed.

### Other Embodiments

Although the present disclosure has been described in accordance with the embodiments, it is understood that the present disclosure is not limited to such embodiments or structures. The present disclosure encompasses various modifications and variations within the scope of equivalents. Furthermore, various combinations and modes, and other combination and modes including only one, more or less element, fall within the spirit and scope of the present disclosure.

For example, in each of the above embodiments, the semiconductor device in which the first semiconductor chip 20 and the second semiconductor chip 30 are sealed with the sealing member 70 has been described. However, the semiconductor device may be configured such that only one semiconductor chip is sealed with the sealing member 70, or may be configured such that three or more semiconductor chips are sealed with the sealing member 70.

In the first and third embodiments, the configuration in which the thermal diffusion plate 90 is disposed in the first sealing member 71 has been described. However, the thermal diffusion plate 90 may also be disposed in the second sealing member 72 as long as the thermal diffusion plate 90 is disposed between the power module PM and the wiring substrate 60.

Furthermore, in each of the above embodiments, the area, the thermal conductivity, the thickness, and the like of the thermal diffusion plate 90 can be appropriately changed.

In addition, each of the above embodiments can be combined as appropriate. For example, the second embodiment may be combined with the third embodiment so that the third connection terminal 53 also functions as the thermal diffusion plate 90.

What is claimed is:

1. A semiconductor device comprising:
a semiconductor module including a semiconductor chip in which a semiconductor element is disposed;
a wiring substrate electrically connected to the semiconductor module;
a sealing member sealing the semiconductor module and the wiring substrate; and
a thermal diffusion plate disposed between the semiconductor module and the wiring substrate, and having a thermal conductivity higher than a thermal conductivity of the sealing member, wherein
the thermal diffusion plate has a plate shape and is disposed in the sealing member in a state where a plane direction of the thermal diffusion plate is along a direction intersecting an arrangement direction of the semiconductor module and the wiring substrate.

2. The semiconductor device according to claim 1, wherein
the sealing member includes a first sealing member that seals the semiconductor module and a second sealing member that seals the wiring substrate, and
the first sealing member and the second sealing member are bonded to each other via a bonding layer.

3. The semiconductor device according to claim 1, wherein
the semiconductor module and the wiring substrate are mechanically connected to each other through a support portion, and
the sealing member integrally seals the semiconductor module and the wiring substrate.

4. The semiconductor device according to claim 1, wherein
an area of a surface of the thermal diffusion plate that intersects the arrangement direction of the semiconductor module and the wiring substrate is twice or more of an area of a surface of the semiconductor chip that intersects the arrangement direction of the semiconductor module and the wiring substrate.

5. The semiconductor device according to claim 1, wherein
the thermal diffusion plate is made of a material having a thermal conductivity that is ten times or more of a thermal conductivity of the sealing member.

6. The semiconductor device according to claim 1, wherein
the thermal diffusion plate has a thickness of 1 mm or less along the arrangement direction of the semiconductor module and the wiring substrate.

7. The semiconductor device according to claim 1, wherein
the thermal diffusion plate is made of a material whose thermal conductivity is higher in the plane direction than in a thickness direction of the thermal diffusion plate, and
the thickness direction of the thermal diffusion plate is a direction along the arrangement direction of the semiconductor element and the wiring substrate.

8. The semiconductor device according to claim 1, wherein
the thermal diffusion plate is disposed in a state where a part of the thermal diffusion plate protrudes from the sealing member.

9. The semiconductor device according to claim 8, wherein
the semiconductor module further includes a connection terminal that is connected to the semiconductor chip,
a part of the connection terminal protrudes from the sealing member, and the thermal diffusion plate and the connection terminal protrude from different surfaces of the sealing member.

10. The semiconductor device according to claim 1, wherein
the thermal diffusion plate is insulated from the semiconductor chip and the wiring substrate.

11. The semiconductor device according to claim 1, wherein
the semiconductor module includes a coupling member and a connection terminal,
the coupling member is connected to a surface of the semiconductor chip that faces the wiring substrate, and the coupling member has a protruding portion that protrudes from the semiconductor chip in a normal direction,
the connection terminal is connected to the protruding portion of the connection terminal and has a portion facing the semiconductor chip in the arrangement direction of the semiconductor module and the wiring substrate, and
the thermal diffusion plate is configured by the connection terminal.

12. The semiconductor device according to claim 11, wherein
the semiconductor module further includes a support substrate to which the semiconductor chip is disposed, and
the connection terminal is thermally connected to the support substrate.
